(19) United States
(12) Patent Application Publication
(10) Pub. No.: US 2025/0323465 A1
(43) Pub. Date: Oct. 16, 2025

(54) NOVEL DETACHABLE ADAPTER

(71) Applicant: Shenzhen Depintong Electronics Co., Ltd., Shenzhen (CN)

(72) Inventor: Peng ZHANG, Zaozhuang (CN)

(73) Assignee: Shenzhen Depintong Electronics Co., Ltd., Shenzhen (CN)

(21) Appl. No.: 18/636,659

(22) Filed: Apr. 16, 2024

(51) Int. Cl. H01R 31/06; H01R 12/71; H01R 13/24; H01R 13/66

(52) U.S. Cl. CPC H01R 31/065; H01R 12/712; H01R 13/2471; H01R 13/6675

(57) ABSTRACT

The present disclosure relates to the technical field of power adapters, and in particular to a novel detachable adapter. The novel detachable adapter includes a power supply body and an adapter body, where a slot is provided on the power supply body, several male pogo pin plugs are arranged at a bottom of the slot, a circuit board is arranged at a rear of the slot of the power supply body, and the male pogo pin plugs are in communication with the circuit board; and one end of the adapter body is provided with metal circular contacts making contact with the several male pogo pin plugs for electric conduction, the other end of the adapter body is provided with a connector matching an apparatus, and the circular contacts are connected to the connector matching the apparatus.

### TECHNICAL FIELD

The present disclosure relates to the technical field of power adapters, and in particular to a novel detachable adapter.

### BACKGROUND

A single cylindrical power supply body with a plug on the market has a fixed and non-split plug, which cannot be replaced with two or more connectors to charge other apparatuses compatibly, and has the defect that only one or one type of apparatuses can be charged, thereby limiting its application scenarios. The patent of the present disclosure provides a body supplying power to multiple or multiple series of apparatuses, thereby reducing purchase cost of a consumer or a demander, and reducing energy consumption and garbage generation to achieve energy-saving and emission reduction effects.

### SUMMARY

A main objective of the present disclosure is to provide a novel detachable adapter, so as to effectively solve the problem put forward in the background.

In order to achieve the above objective, the patent of the present disclosure uses the following technical solution: a novel detachable adapter includes a power supply body and an adapter body, where a slot is provided on the power supply body, several male pogo pin plugs are arranged at a bottom of the slot, a circuit board is arranged at a rear of the slot of the power supply body, and the male pogo pin plugs are in communication with the circuit board; and one end of the adapter body is provided with metal circular contacts making contact with the several male pogo pin plugs for electric conduction, the other end of the adapter body is provided with a connector matching an apparatus, and the circular contacts are connected to the connector matching the apparatus.

Preferably, a recess is provided on a side wall of the slot of the power supply body, a boss is arranged at one end of the adapter body inserted into the power supply body to match the recess, and the adapter body has a shape matching the slot and is inserted into the slot.

Preferably, two side surfaces of one end of the adapter body inserted into the slot on the power supply body are each provided with a long bump and a short bump, two side walls in the slot are each provided with an arc-shaped protruding strip, and when the adapter body is inserted into the slot on the power supply body, the arc-shaped protruding strip is clamped between the long bump and the short bump to fix the long bump and the short bump, and the several male pogo pin plugs make contact with the circular contacts on the adapter body in a one-to-one corresponding manner.

Preferably, the power supply body is a mobile power supply or charger.

Preferably, one end of the adapter body matching the apparatus is an iphone operation system (ios) connector, a Type-c connector, a connector having a diameter of 3.5 millimeters, a double-head plug, a double-hole plug, a three-head plug, a three-hole plug, an American standard plug and a European standard plug.

The patent of the present disclosure has the beneficial effects: power is supplied to different apparatuses through one power supply body plus different replaceable plugs, thereby reducing use cost of a consumer, and reducing energy consumption and garbage generation.

### BRIEF DESCRIPTION OF DRAWINGS

FIG. 1 is a schematic structural diagram of the patent of the present disclosure.

FIG. 2 is a schematic sectional view of a plug-in structure of the disclosure.

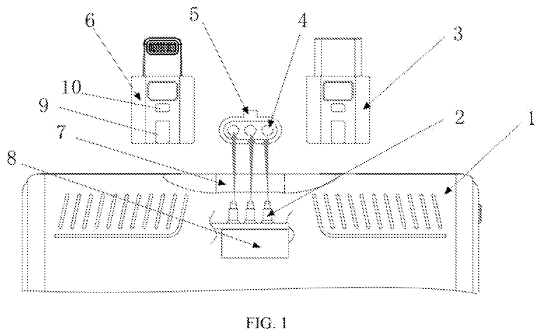

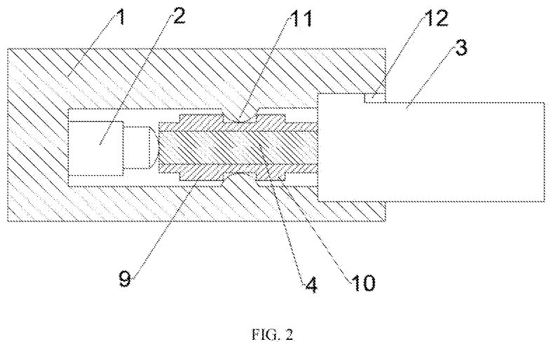

In FIGS. 1 and 2, power supply body 1, male pogo pin plug 2, Type-c connector 3, circular contact 4, boss 5, iphone operation system (ios) connector 6, slot 7, circuit board 8, long bump 9, short bump 10, arc-shaped protruding strip 11, and recess 12.

### DETAILED DESCRIPTION OF THE EMBODIMENTS

The technical solutions in the examples of the patent of the present disclosure will be clearly and completely described below in combination with the examples of the patent of the present disclosure. Apparently, the examples described are only some examples rather than all examples of the patent of the present disclosure. All other examples obtained by those of ordinary skill in the art on the basis of the examples of the patent of the present disclosure without making creative efforts shall fall within the scope of protection of the patent of the present disclosure.

### Example 1

As shown in FIGS. 1 and 2, a novel detachable adapter includes a power supply body 1 and an adapter body, where a slot 7 is provided on the power supply body 1, three male pogo pin plugs 2 are arranged at a bottom of the slot 7, a circuit board 8 is arranged at a rear of the slot of the power supply body 7, and the male pogo pin plugs 2 are in communication with the circuit board 8; and one end of the adapter body is provided with metal circular contacts 4 making contact with the three male pogo pin plugs 2 for electric conduction, the other end of the adapter body is provided with a connector matching an apparatus, and the circular contacts 4 are connected to the connector matching the apparatus.

A recess 12 is provided on a side wall of the slot 7 of the power supply body, a boss 5 is arranged at one end of the adapter body inserted into the power supply body to match the recess 12, and the adapter body has a shape matching the slot 7 and is inserted into the slot 7.

Two side surfaces of one end of the adapter body inserted into the slot 7 on the power supply body 1 are each provided with a long bump 9 and a short bump 10, two side walls in the slot 7 are each provided with an arc-shaped protruding strip 11, and when the adapter body is inserted into the slot 7 on the power supply body 1, the arc-shaped protruding strip 11 is clamped between the long bump 9 and the short bump 10 to fix the long bump and the short bump, and the three male pogo pin plugs 2 make contact with the circular contacts 4 on the adapter body in a one-to-one corresponding manner.

The power supply body is a mobile power supply or charger.

One end of the adapter body matching the apparatus is an iphone operation system (ios) connector 6 and a Type-c connector 3.

The patent of the present disclosure has the beneficial effects: power is supplied to different apparatuses through one power supply body plus different replaceable plugs, thereby reducing use cost of a consumer, and reducing energy consumption and garbage generation.

Although the patent of the present disclosure is described in detail with reference to the above examples, those skilled in the art can still make modifications to the technical solutions described in the above examples, or make equivalent substitutions to part of the technical features in the technical solutions. Any modification, equivalent substitution, improvement, etc. made within the spirit and the principle of the patent of the present disclosure should all fall within the scope of protection of the patent of the present disclosure.

What is claimed is:

1. A novel detachable adapter, comprising: a power supply body and an adapter body, wherein a slot is provided on the power supply body, several male pogo pin plugs are arranged at a bottom of the slot, a circuit board is arranged at a rear of the slot of the power supply body, and the male pogo pin plugs are in communication with the circuit board; and one end of the adapter body is provided with metal circular contacts making contact with the several male pogo pin plugs for electric conduction, the other end of the adapter body is provided with a connector matching an apparatus, and the circular contacts are connected to the connector matching the apparatus.

2. The novel detachable adapter according to claim 1, wherein a recess is provided on a side wall of the slot of the power supply body, a boss is arranged at one end of the adapter body inserted into the power supply body to match the recess, and the adapter body has a shape matching the slot and is inserted into the slot.

3. The novel detachable adapter according to claim 1, wherein two side surfaces of one end of the adapter body inserted into the slot on the power supply body are each provided with a long bump and a short bump, two side walls in the slot are each provided with an arc-shaped protruding strip, and when the adapter body is inserted into the slot on the power supply body, the arc-shaped protruding strip is clamped between the long bump and the short bump to fix the long bump and the short bump, and the several male pogo pin plugs make contact with the circular contacts on the adapter body in a one-to-one corresponding manner.

4. The novel detachable adapter according to claim 1, wherein the power supply body is a mobile power supply or charger.

5. The novel detachable adapter according to claim 1, wherein one end of the adapter body matching the apparatus is an iphone operation system (ios) connector, a Type-c connector, a connector having a diameter of 3.5 millimeters, a double-head plug, a double-hole plug, a three-head plug, a three-hole plug, an American standard plug and a European standard plug.
